(19) United States
(12) Patent Application Publication
(10) Pub. No.: US 2025/0357732 A1
(43) Pub. Date: Nov. 20, 2025

(54) BUSBAR BRACKET

(71) Applicant: Quanta Computer Inc., Taoyuan City (TW)

(72) Inventors: Yaw-Tzorng TSORNG, Taoyuan City (TW); Ming-Lung WANG, Taoyuan City (TW); Hung-Wei CHEN, Taoyuan City (TW); Liang-Ju LIN, Taoyuan City (TW)

(21) Appl. No.: 18/663,629

(22) Filed: May 14, 2024

(51) Int. Cl. H02B 1/21; H02B 1/20; H05K 7/14

(52) U.S. Cl. CPC H02B 1/21; H02B 1/205; H05K 7/1488

(57) ABSTRACT

A busbar bracket for a computing system is disclosed. The busbar bracket includes a bracket base having a general unitary U-shape formed by two base side walls and a base bottom wall. The unitary U-shape defines a mounting space configured to receive a busbar connector. The mounting space is enclosed along the two base side walls and the base bottom wall. The mounting space has an open side between free ends of the two base side walls. The busbar bracket further includes a bracket cover having two cover side walls slidably attached, respectively, to the free ends of the two base side walls. The bracket cover is movable between a coupled position and an uncoupled position. The bracket cover encloses the open side and prevents removal of the busbar connector in the coupled position.

### FIELD OF THE INVENTION

The present invention relates generally to a busbar bracket for a computing system, and more specifically, to a busbar bracket configured to receive a busbar connector and for attachment to a computer chassis. Conventional busbar brackets usually require a number of loose parts, such as screws, for assembly. In contrast, the inventive busbar bracket does not require a number of loose parts for assembly. The busbar bracket has an easy sliding mechanism for coupling/uncoupling the busbar connector. Therefore, the busbar bracket can be used to securely attach the busbar connector enclosed within the busbar bracket to the computer chassis without requiring multiple assembly steps.

### BACKGROUND OF THE INVENTION

In general, busbar connectors are installed at a rear side of a computer chassis or server chassis. The main function of the busbar connector is to provide power distribution. A conventional way of installing a busbar connector in a module or busbar bracket is shown in FIGS. 1A and 1B. Referring to FIG. 1A, the prior art module 100 has a module base 110, a lower cover 120, and an upper cover 130 that are completely separate when the module 100 is not assembled. The separate parts consisting of the module base 110, the lower cover 120, and the upper cover 130 need to be assembled to fix a busbar connector 200 within the assembled module 100. First, as shown in FIG. 1A, the busbar connector 200 is inserted to the module base 110. Then, as shown in FIG. 1A, the lower cover 120 and the upper cover 130 are placed on bottom and top sides, respectively, of the module base 110 to form an assembled module 100. To lock the busbar connector 200 within the assembled module 100, the lower cover 120 and the upper cover 130 are fastened to the module base 110 by using screws. For example, four screws are inserted into through holes at four corner areas of the lower cover 120, and four screws are inserted into through holes at four corner areas of the upper cover 130. In FIG. 1B, the through holes receiving the screws are indicated by arrows. The screws passing through the through holes of the lower cover 120 and the upper cover 130 are fastened to respective through holes formed at the module base 110. Once all the screws are fastened, the busbar connector 200 enclosed within the assembled module 100 is securely locked therein. Further, the assembled module 100, with the busbar connector 200 therein, is attached to the rear side of the computer/server chassis, and at least four screws are required for the attachment of the module 100 to the computer/server chassis (not shown in drawings). Therefore, too many loose parts, such as screws, are required for assembling the module 100 that encloses the busbar connector 200 and attaches the assembled module 100 to the computer/server chassis. For that reason, it may take long to assemble the prior art module 100 using a number of screws.

Therefore, a need exists for solving the problem of inefficiency caused by a long assembly time required for assembling a module that encloses a busbar connector therein. A need also exists for reducing the number of parts required for assembling the module that encloses the busbar connector therein to improve the efficiency of assembling the module.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

In view of the above-described problem with conventional modules/brackets for enclosing a busbar connector, the present application discloses a busbar bracket for a computing system that provides a simpler way of enclosing a busbar connector therein. Using the inventive busbar bracket, a busbar connector can be enclosed within the busbar bracket easily without requiring a number of parts. Thus, the inventive busbar bracket allows reducing the assembly time and provides a more efficient way of attaching the busbar connector to a computer chassis.

According to certain aspects of the present disclosure, a busbar bracket for a computing system is disclosed. According to various embodiments, the busbar bracket includes a bracket base having a general unitary U-shape formed by two base side walls and a base bottom wall. The unitary U-shape defines a mounting space configured to receive a busbar connector. The mounting space is enclosed along the two base side walls and the base bottom wall, and has an open side between free ends of the two base side walls. The busbar bracket further includes a bracket cover having two cover side walls slidably attached, respectively, to the free ends of the two base side walls. The bracket cover is movable between a coupled position and an uncoupled position. The bracket cover encloses the open side and prevents removal of the busbar connector in the coupled position.

In various embodiments, the bracket base further has a first mounting ear extending from a first base side wall of the two base side walls; and a second mounting ear extending from a second base side wall of the two base side walls.

In various embodiments, the first mounting ear and the second mounting ear are perpendicular to the two base side walls.

In various embodiments, each of the first mounting ear and the second mounting ear has at least one through hole configured to receive a first fastener.

In various embodiments, the busbar bracket is configured for attachment to a computer chassis. The first fastener passes through the at least one through hole to fasten the busbar bracket to the computer chassis.

In various embodiments, the bracket cover further has a cover top wall connecting the two cover side walls, a third mounting ear, and a fourth mounting ear. The third mounting ear and the fourth mounting ear extend from the cover top wall.

In various embodiments, the cover top wall has the third and fourth mounting ears and has a T-shape.

In various embodiments, each of the third mounting ear and the fourth mounting ear has at least one through hole configured to receive a second fastener.

In various embodiments, the second fasteners passing through the through holes of the third mounting ear and the fourth mounting ear are configured to fasten the busbar bracket to the computer chassis.

In various embodiments, the fastener is at least partially threaded or comprises a screw and configured to be fastened to the cabinet.

In various embodiments, each of the first fastener and the second fastener is at least partially threaded or comprises a screw.

In various embodiments, the first and second mounting ears are perpendicular to the third and fourth mounting ears.

In various embodiments, the first and second mounting ears are fastened to a first side of the computer chassis, and the third and fourth mounting ears are fastened to a second side of the computer chassis. The first side of the computer chassis is perpendicular to the second side of the computer chassis.

In various embodiments, the third and fourth mounting ears fastened to the second side of the computer chassis are obscured by a top cover of the computer chassis placed on top of the third and fourth mounting ears.

In various embodiments, each of the two base side walls has two through holes. Each of the two through holes is configured to receive a protrusion. In various embodiments, each of the two cover side walls has two slots respectively corresponding to the two through holes. Each of the two slots is engaged with a corresponding protrusion received in a corresponding one of the two through holes. In various embodiments, the bracket cover is configured to move up and down by sliding of the slots with respect to the protrusions. The bracket cover is in the coupled position when the protrusions are at upper positions of the slots, and the bracket cover is in the uncoupled position when the protrusions are at lower positions of the slots.

In various embodiments, each of the two base side walls has a through hole configured to receive a third fastener. In various embodiments, each of the two cover side walls has a through hole corresponding to the through hole of a corresponding one of the two base side walls. The through holes of the two cover side walls are configured to receive the third fasteners received in the through holes of the two base side walls. In various embodiments, each of the third fasteners is releasably fixed to a corresponding one of the through holes of the two base side walls and a corresponding one of the through holes of the two cover side walls that are aligned when the bracket cover is in the coupled position.

In various embodiments, each of the third fasteners comprises a nut received in the through hole of one of the two cover side walls and a screw received in the through hole of one of the two base side walls. The screw is fastened to the nut.

According to other aspects of the present disclosure, a computing system is disclosed. According to various embodiments, the computing system includes a computer chassis, a busbar bracket, and a busbar connector. The busbar bracket comprises a bracket base configured for attachment to the computer chassis. The bracket base has a general unitary U-shape formed by two base side walls and a base bottom wall. The unitary U-shape defines a mounting space configured to receive the busbar connector. The mounting space is enclosed along the two base side walls and the base bottom wall. The mounting space has an open side between free ends of the two base side walls. The busbar bracket further comprises a bracket cover having two cover side walls slidably attached, respectively, to the free ends of the two base side walls. The bracket cover is movable between a coupled position and an uncoupled position. The bracket cover encloses the open side and prevents removal of the busbar connector in the coupled position. The bracket cover is configured to move up and down relative to the bracket base. The busbar connector is receivable in the busbar bracket while the bracket cover is in the uncoupled position. The received busbar connector can be fixed in the busbar bracket by the bracket cover moved from the uncoupled position to the coupled position.

In various embodiments, the bracket cover is fixedly coupled to the bracket base by at least two fasteners when the bracket cover is in the coupled position.

In various embodiments, each of the two base side wall has two through holes, and each of the two through holes is configured to receive a protrusion.

In various embodiments, each of the two cover side wall has two slots respectively corresponding to the two through holes, and each of the two slots is engaged with a corresponding protrusion received in a corresponding one of the two through holes.

In various embodiments, the bracket cover is configured to move up and down by sliding the slots with respect to the protrusions. The bracket cover is in the coupled position when the protrusions are at upper positions of the slots, and the bracket cover is in the uncoupled position when the protrusions are at lower positions of the slots.

According to other aspects of the present disclosure, a busbar bracket for a computing system is disclosed. According to various embodiments, the busbar bracket includes a bracket base having a base bottom wall; a first base side wall that is perpendicular to the base bottom wall; and a second base side wall that is perpendicular to the base bottom wall. The first base side wall and the second base side wall are parallel. A mounting space is formed between the first base side wall and the second base side wall. The mounting space is configured to receive a busbar connector. The busbar bracket further includes a bracket cover movably coupled to the bracket base. The bracket cover has a cover top wall; a first cover side wall that is perpendicular to the cover top wall; and a second cover side wall that is perpendicular to the cover top wall. The first cover side wall and the second cover side wall are parallel. The cover top wall and the base bottom wall are parallel. The bracket cover is configured to move up and down relative to the bracket base. The busbar connector is receivable in the busbar bracket while the bracket cover is in an up position. The received busbar connector can be fixed in the busbar bracket by the bracket cover moved from the up position to a down position.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1A is an exploded perspective view of a prior art busbar bracket assembly for receiving a busbar connector.

FIG. 1B is an assembled perspective view of the prior art busbar bracket assembly shown in FIG. 1A with the busbar connector received therein.

FIG. 2A is an assembled perspective view of a busbar bracket, according to certain aspects of the present disclosure.

FIG. 2B is an exploded perspective view of the busbar bracket shown in FIG. 2A, according to aspects of the present disclosure.

FIGS. 3A-3D are perspective views of the busbar bracket shown in FIG. 2A in various configurations. FIGS. 3A-3D show how the busbar bracket is operated to receive and fix a busbar connector in the busbar bracket, according to certain aspects of the present disclosure.

FIG. 4A is a perspective view of the busbar bracket shown in FIG. 2A attached to a computer chassis without a top cover, according to certain aspects of the present disclosure.

FIG. 4B is a perspective view of the busbar bracket shown in FIG. 4A attached to the computer chassis with a top cover, according to certain aspects of the present disclosure.

### DETAILED DESCRIPTION

Various embodiments are described with reference to the attached figures, where like reference numerals are used throughout the figures to designate similar or equivalent elements. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

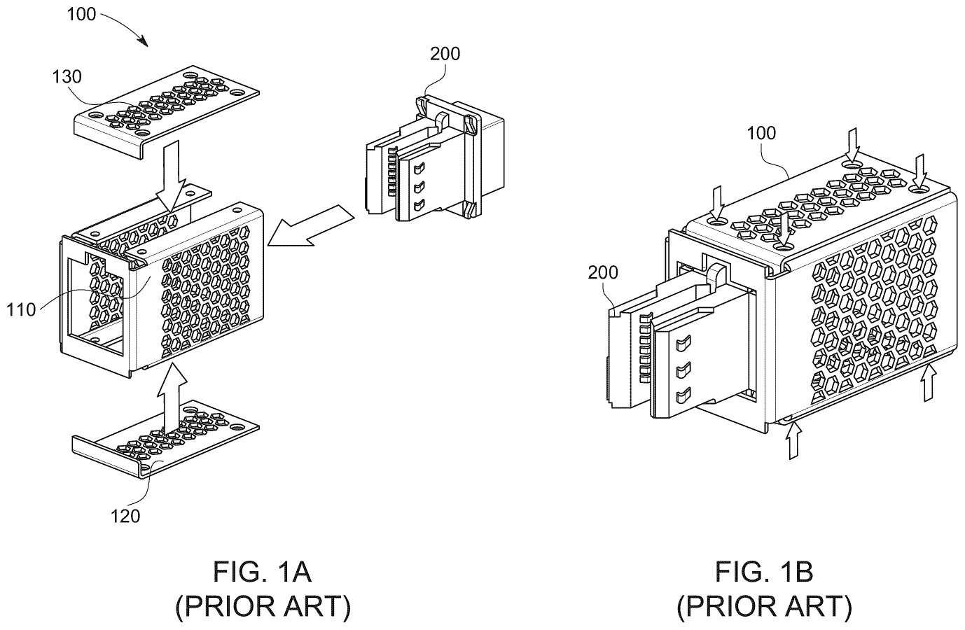

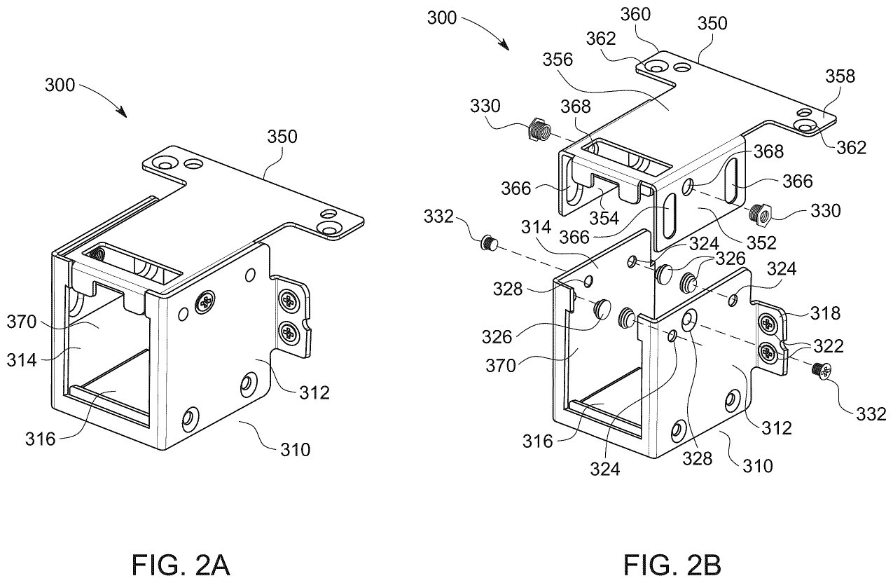

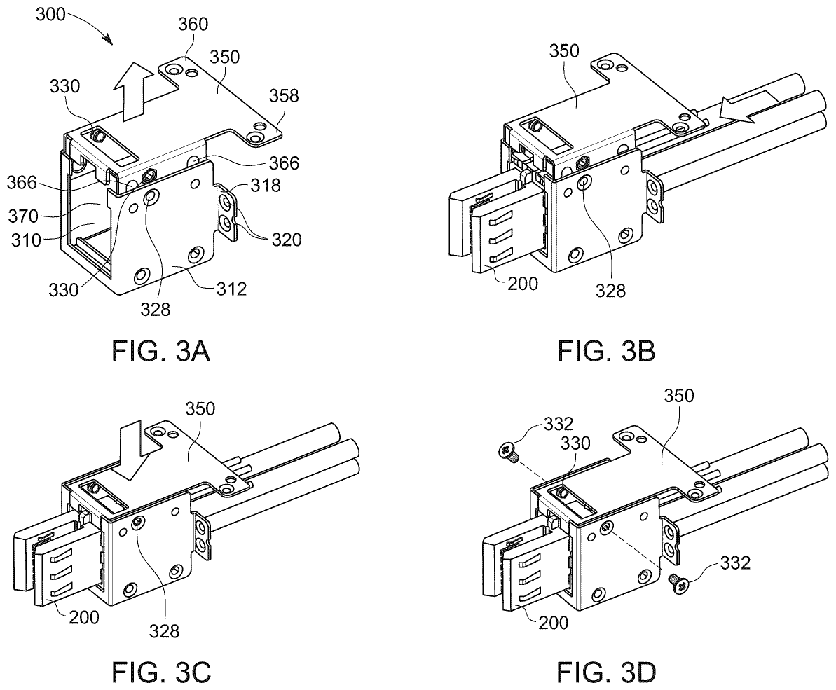

Referring to FIGS. 2A and 2B, a busbar bracket 300, according to various embodiments of the present invention, includes a bracket base 310 having a general unitary U-shape formed by two base side walls 312, 314 and a base bottom wall 316. The unitary U-shape defines a mounting space 370 configured to receive a busbar connector, such as the busbar connector 200 (FIGS. 1A and 1B). The mounting space 370 is enclosed along the two base side walls 312, 314 and the base bottom wall 316. The mounting space 370 has an open side between free ends of the two base side walls 312, 314. The busbar bracket 300 further includes a bracket cover 350 having two cover side walls 352, 354 slidably attached, respectively, to the free ends of the two base side walls 312, 314. The first base side wall 312 and the second base side wall 314 are parallel to allow sliding of the bracket cover 350. The bracket cover 350 is movable between a coupled position and an uncoupled position, and this feature will be discussed in detail, referring to FIGS. 3A-3D.

Further referring to FIGS. 2A and 2B, the bracket base 310 further has a first mounting ear 318 extending from the first base side wall 312 and a second mounting ear (not shown in drawings) extending from the second base side wall 314. The first mounting ear 318 and the second mounting ear are perpendicular to the two base side walls 312, 314. Each of the first mounting ear 318 and the second mounting ear has at least one through hole 320 configured to receive a first fastener 322. In some embodiments, the first fastener 322 is a screw.

Further referring to FIGS. 2A and 2B, the bracket cover 350 further has a cover top wall 356 connecting the two cover side walls 352, 354. A third mounting ear 358 extends from the cover top wall 356, and a fourth mounting ear 360 extends from the cover top wall 356. The base side walls 312, 314 and the cover side walls 352, 354 are parallel. The cover top wall 356 is perpendicular to the cover side walls 352, 354. In one embodiment, the cover top wall 356 having the third and fourth mounting ears 358, 360 has a T-shape. Each of the third mounting ear 358 and the fourth mounting ear 360 has at least one through hole 362 configured to receive a fastener.

Further referring to FIGS. 2A and 2B, each of the two base side walls 312, 314 has two through holes 324. Each of the two through holes 324 is configured to receive a protrusion 326. Each of the two cover side walls 352, 354 has two slots 366 respectively corresponding to the two through holes 324. Each of the two slots 366 is engaged with a corresponding protrusion 326 received in a corresponding one of the two through holes 324. In some embodiments, the protrusions 326 passing through the slots 366 and inserted into the through holes 324 of the base side walls 312, 314 slidably fix the bracket cover 350 to the bracket base 310. Thus, unless the protrusions 326 are removed from the through holes 324 of the base side walls 312, 314, the bracket base 310 and the bracket cover 350 are always in a coupled state. The bracket cover 350 is configured to move up and down by sliding of the slots 366 with respect to the protrusions 326.

Further referring to FIGS. 2A and 2B, each of the two base side walls 312, 314 has a through hole 328 configured to receive a third fastener 330, 332. Each of the two cover side walls 352, 354 has a through hole 368 corresponding to the through hole 328 of a corresponding one of the two base side walls 312, 314. For example, the third fastener 330 is received within each of the two through holes 368 of the two cover side walls 352, 354. The third fastener 332 is received in each of the two through holes 328 of the two base side walls 312, 314. Each of the third fasteners 330, 332 is releasably fixed to a corresponding one of the through holes 328 of the two base side walls 312, 314, and a corresponding one of the through holes 368 of the two cover side walls 352, 354 that are aligned when the bracket cover 350 is in the coupled position.

In some embodiments, each of the third fasteners 330, 332 includes a nut 330 received in the through hole 368 of one of the two cover side walls 352, 354 and a screw 332 received in the through hole of one of the two base side walls 312, 314. The screw 332 is fastened to the nut 330 to make the slots 366 not slidable with respect to the protrusions 326. According to the example shown in the drawings, each of the third fasteners 330, 332 includes two components, a nut 330 and a screw 332. However, in some embodiments, the third fasteners 330, 332 may be implemented as a single component instead. For example, the third fasteners 330, 332 implemented as a single component is a screw that is fastened to the through hole 368 and the through hole 328.

FIGS. 3A-3D show how the busbar bracket 300 is operated to receive and fix a busbar connector 200 in the busbar bracket, according to certain aspects of the present disclosure. Briefly, FIGS. 3A and 3B show the bracket cover 350 in an uncoupled position when the protrusions 326 (shown in FIG. 2B) are at lower positions of the slots 366. FIGS. 3C and 3D show the bracket cover 350 in a coupled position when the protrusions 326 are at upper positions of the slots 366. FIG. 3D shows that the bracket cover 350 encloses the open side of the mounting space 370 defined in the bracket base 310, thus preventing removal of the busbar connector 200 in the coupled position.

Referring to FIG. 3A, a method of attaching a busbar connector 200 to the busbar bracket 300 includes raising the bracket cover 350 of the busbar bracket 300 from a down position (or coupled position) to an up position (or uncoupled position) by moving the bracket cover 350 slidably coupled to a bracket base 310 of the busbar bracket 300 in the direction of the arrow.

Referring to FIG. 3B, the busbar connector 200 is inserted in the direction of arrow to a mounting space 370 formed between the first base side wall 312 and the second base side wall 314 of the bracket base 310 (all three shown in FIG. 2B) while the bracket cover 350 is in the up position. The through holes 328 of the first base side wall 312 and the second base side wall 314 (shown in FIG. 2B) are not aligned with the through holes 368 (shown in FIG. 2B) of the cover side walls 352, 354 (shown in FIG. 2B) when the bracket cover 350 is in the up position. When the through holes 328, 368 are not aligned, the fasteners 330, 332 cannot be fastened to the base side walls 312, 314 of the bracket base 310 and to the cover side walls 352, 354 of the bracket cover 350.

Referring to FIG. 3C, after the busbar connector 200 is inserted to the mounting space 370 (FIG. 3B), the bracket cover 350 is lowered in the direction of arrow to the down position to fix the busbar connector 200 in the mounting space 370. In this configuration of the busbar bracket 300 in which the bracket cover 350 is in the down position, the through holes 328, 368 are aligned to receive the fasteners 330, 332.

Referring to FIG. 3D, the bracket cover 350 that is in the down position is fixed to the bracket base 310 by fastening fasteners, such as nuts 330 and screws 332, to the first and second side base walls 312, 314 of the bracket base 310 and to the cover side walls 352, 354 of the bracket cover 350. Since the cover side walls 352, 354 are parallel and the base side walls 312, 314 and the cover side walls 352, 354 have through holes 328, 368, respectively, as shown in FIG. 2B, the through holes 328, 368 are aligned when the bracket cover 350 is in the down position, as shown in FIGS. 3C and 3D.

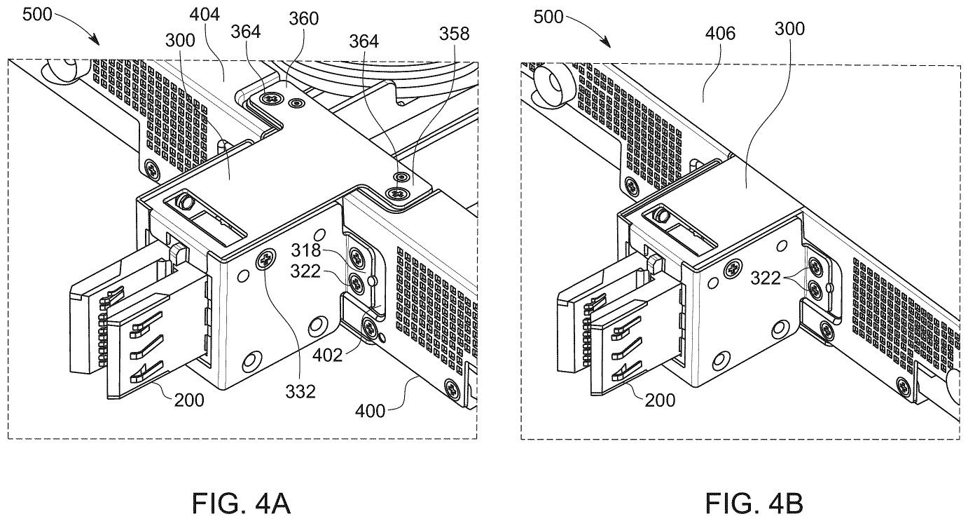

Referring to FIGS. 4A and 4B, the busbar bracket 300 shown in FIG. 2A is attached to a computer chassis 400 of a computing system 500, according to certain aspects of the present disclosure. Specifically, the computing system 500 includes the busbar bracket 300 and the busbar connector 200. The structure and components of the busbar bracket 300, and the busbar bracket 300 enclosing the busbar connector 200, have been discussed above, referring to FIGS. 2A-3D, and thus, will not be repeated here.

The assembled busbar bracket 300 with the busbar connector 200 fixed therein, as shown in FIG. 3D, is attached to the computer chassis 400 by fastening the first mounting ear 318 and second mounting ear (not shown in drawings) to a first side 402 of the computer chassis 400 with first fasteners 322. The first fasteners 322 pass through the through holes 320 (shown in FIGS. 2A, 2B, and 3A) of the first 318 and second (not shown in drawings) mounting ears to fasten the busbar bracket 300 to the computer chassis 400. Further, the third mounting ear 358 and fourth mounting ear 360 are fastened to a second side 404 of the computer chassis 400 with second fasteners 364. The first side 402 of the computer chassis 400 is perpendicular to the second side 404.

The second fasteners 364 passing through the through holes 362 (shown in FIG. 2B) of the third mounting ear 358 and the fourth mounting ear 360 are configured to fasten the busbar bracket 300 to the computer chassis 400. Each of the first fastener 322 and the second fastener 364 is at least partially threaded or includes a screw. The first mounting ear 318 and the second mounting ear (not shown in drawings) are perpendicular to the third mounting ear 358 and the fourth mounting ear 360. The first 318 and second mounting ears (not shown in drawings) are fastened to a first side 402 of the computer chassis 400, and the third and fourth mounting ears 358, 360 are fastened to a second side 404 of the computer chassis 400. In the computer chassis 400, the first side 402 is perpendicular to the second side 404. The third and fourth mounting ears 358, 360 fastened to the second side 404 of the computer chassis 400 are obscured by a top cover 406 of the computer chassis 400 placed on top of the third and fourth mounting ears 358, 360.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A busbar bracket for a computing system, the busbar bracket comprising:
a bracket base having a general unitary U-shape formed by two base side walls and a base bottom wall, the unitary U-shape defining a mounting space configured to receive a busbar connector, the mounting space being enclosed along the two base side walls and the base bottom wall, the mounting space having an open side between free ends of the two base side walls; and
a bracket cover having two cover side walls slidably attached, respectively, to the free ends of the two base side walls, the bracket cover being movable between a coupled position and an uncoupled position, the bracket cover enclosing the open side and preventing removal of the busbar connector in the coupled position.

2. The busbar bracket of claim 1, wherein the bracket base further has:
a first mounting ear extending from a first base side wall of the two base side walls; and
a second mounting ear extending from a second base side wall of the two base side walls.

3. The busbar bracket of claim 2, wherein the first mounting ear and the second mounting ear are perpendicular to the two base side walls.

4. The busbar bracket of claim 3, wherein each of the first mounting ear and the second mounting ear has at least one through hole configured to receive a first fastener.

5. The busbar bracket of claim 4, wherein the busbar bracket is configured for attachment to a computer chassis, the first fastener passing through the at least one through hole fastening the busbar bracket to the computer chassis.

6. The busbar bracket of claim 5, wherein the bracket cover further has:
a cover top wall connecting the two cover side walls;
a third mounting ear extending from the cover top wall; and
a fourth mounting ear extending from the cover top wall.

7. The busbar bracket of claim 6, wherein the cover top wall, having the third and fourth mounting ears, has a T-shape.

8. The busbar bracket of claim 6, wherein each of the third mounting ear and the fourth mounting ear has at least one through hole configured to receive a second fastener.

9. The busbar bracket of claim 8, wherein the second fasteners passing through the through holes of the third mounting ear and the fourth mounting ear are configured to fasten the busbar bracket to the computer chassis.

10. The busbar bracket of claim 9, wherein each of the first fastener and the second fastener is at least partially threaded or comprises a screw.

11. The busbar bracket of claim 9, wherein the first and second mounting ears are perpendicular to the third and fourth mounting ears.

12. The busbar bracket of claim 11, wherein the first and second mounting ears are fastened to a first side of the computer chassis, and the third and fourth mounting ears are fastened to a second side of the computer chassis, the first side being perpendicular to the second side.

13. The busbar bracket of claim 12, wherein the third and fourth mounting ears fastened to the second side of the computer chassis are obscured by a top cover of the computer chassis placed on top of the third and fourth mounting ears.

14. The busbar bracket of claim 1, wherein:
each of the two base side walls has two through holes, each of the two through holes being configured to receive a protrusion;
each of the two cover side walls has two slots respectively corresponding to the two through holes, each of the two slots being engaged with a corresponding protrusion received in a corresponding one of the two through holes; and
the bracket cover is configured to move up and down by sliding the slots with respect to the protrusions, the bracket cover being in the coupled position when the protrusions are at upper positions of the slots, and the bracket cover being in the uncoupled position when the protrusions are at lower positions of the slots.

15. The busbar bracket of claim 1, wherein:
each of the two base side walls has a through hole configured to receive a third fastener;
each of the two cover side walls has a through hole corresponding to the through hole of a corresponding one of the two base side walls, the through holes of the two cover side walls being configured to receive the respective third fasteners received in the respective through holes of the two base side walls; and
each of the third fasteners passes through a corresponding one of the through holes of the two base side walls and a corresponding one of the through holes of the two cover side walls that are aligned when the bracket cover is in the coupled position.

16. The busbar bracket of claim 15, wherein each of the third fasteners comprises:
a nut received in the through hole of one of the two cover side walls; and
a screw received in the through hole of one of the two base side walls, and
wherein the screw is fastened to the nut.

17. A computing system comprising:
a computer chassis;
a busbar bracket; and
a busbar connector,
wherein the busbar bracket comprises:
a bracket base configured for attachment to the computer chassis, the bracket base having a general unitary U-shape formed by two base side walls and a base bottom wall, the unitary U-shape defining a mounting space configured to receive the busbar connector, the mounting space being enclosed along the two base side walls and the base bottom wall, the mounting space having an open side between free ends of the two base side walls; and
a bracket cover having two cover side walls slidably attached, respectively, to the free ends of the two base side walls, the bracket cover being movable between a coupled position and an uncoupled position, the bracket cover enclosing the open side and preventing removal of the busbar connector in the coupled position,
wherein the bracket cover is configured to move up and down relative to the bracket base, the busbar connector receivable in the busbar bracket while the bracket cover is in the uncoupled position and the received busbar connector being fixed in the busbar bracket by the bracket cover moved from the uncoupled position to the coupled position.

18. The computing system of claim 17, wherein the bracket cover is fixedly coupled to the bracket base by at least two fasteners when the bracket cover is in the coupled position.

19. The computing system of claim 18, wherein:
each of the two base side wall has two through holes, each of the two through holes being configured to receive a protrusion;
each of the two cover side walls has two slots respectively corresponding to the two through holes, each of the two slots being engaged with a corresponding protrusion received in a corresponding one of the two through holes; and
the bracket cover is configured to move up and down by sliding of the slots with respect to the protrusions, the bracket cover being in the coupled position when the protrusions are at upper positions of the slots, and the bracket cover being in the uncoupled position when the protrusions are at lower positions of the slots.

20. A busbar bracket for a computing system, the busbar bracket comprising:
a bracket base having a base bottom wall, a first base side wall that is perpendicular to the base bottom wall, and a second base side wall that is perpendicular to the base bottom wall, the first base side wall and the second base side wall being parallel, a mounting space being formed between the first base side wall and the second base side wall, and the mounting space being configured to receive a busbar connector; and
a bracket cover movably coupled to the bracket base, the bracket cover having a cover top wall, a first cover side wall that is perpendicular to the cover top wall, and a second cover side wall that is perpendicular to the cover top wall, the first cover side wall and the second cover side wall being parallel, and the cover top wall and the base bottom wall being parallel,
wherein the bracket cover is configured to move up and down relative to the bracket base, the busbar connector receivable in the busbar bracket while the bracket cover is in an up position and the received busbar connector being fixed in the busbar bracket by the bracket cover moved from the up position to a down position.
